(19) United States
(12) Patent Application Publication
(10) Pub. No.: US 2025/0370070 A1
(43) Pub. Date: Dec. 4, 2025

(54) METHOD OF DETERMINING A FAILURE RATE FOR AN ELECTRICAL CONNECTOR

(71) Applicant: Aptiv Technologies AG, Schaffhausen (CH)

(72) Inventor: Maxime PORTE, Nuremberg (DE)

(21) Appl. No.: 19/214,406

(22) Filed: May 21, 2025

(30) Foreign Application Priority Data
May 28, 2024 (EP) 24178495.8

(51) Int. Cl. G01R 31/68

(52) U.S. Cl. CPC G01R 31/68

(57) ABSTRACT

A method for determining the failure rate of a batch of electrical connectors involves degrading at least one sample connector to exhibit a normal contact force below a specified threshold, which is less than the batch's mean force. The method includes determining the probability of the sample's occurrence within the batch based on the threshold force, applying a vibration test to the sample, and obtaining its failure rate. The batch's failure rate is then calculated by multiplying the sample's failure rate by its probability of occurrence. This approach allows for an accurate estimation of the batch's overall reliability by assessing the performance of degraded samples under specified conditions.

### CROSS-REFERENCE TO RELATED APPLICATION

This application claims the benefit of and priority to European Application No. 24178495.8 filed with the European Patent Office on May 28, 2024, the contents of which are incorporated by reference herein.

### TECHNICAL FIELD

The present disclosure relates to a method for determining a failure rate of an electrical connector.

### BACKGROUND

Electrical connector and terminal failure rates are essential information for evaluating the reliability of electrical functions in the field of automotive and especially autonomous driving and e-mobility.

It has been already identified that the possible micro-movement between the male and female terminals due to system vibrations or thermal expansion cycles, is the most contributing factor in the contact degradation, the contact degradation leading to a contact resistance increase, causing electrical failure in field.

Some technical papers report that a minimum number of electrical random failure might happen in a period of 109 operating hours. Accordingly, a failure rate is generally expressed in FIP unit, one FIP being one failure per 109 operating hours.

In the meanwhile, it is important to understand that a standard connector vibration test might be able to simulate around 250,000 operating hours (10 years×500 op. hours per year ×50 samples). This test requires many efforts to be set, and its duration is around 3 weeks. Moreover, due to usual quite stable contact resistances during the test, such a test does not provide enough failures to be significant. Any extrapolation to failure (to evaluate the life duration) will be either impossible or at least associated with low confidence in the result, when the time window of extrapolation is too large.

So, several options might be considered to increase the number of simulated operating hours to avoid false result extrapolation from product validation testing (in which no or minimum wear/micro-movements happen):
repeat the vibration test by a multiplicative factor X until obtaining significant product failures. A major drawback is the tremendous amount of time needed,
make the test more severe (by raising temperature/vibration amplitude) with a multiplicative factor Y to cause earlier failures. The problem is mainly that test conditions are already set close to the limits to match field degradation mechanisms. In case of any more severe testing, there is a strong risk to activate other degradation mechanisms (material fatigue and wear) that could not be correlated to reality/field experience anymore.
increase the quantity of samples in test by a multiplicative factor Z. Here again a major drawback is the increased sample cost. Testing typically uses about fifty samples. Increasing the number of connector test samples is not desirable due to increased cost of producing up to one thousand of what are usually prototype-level parts.

The points presented above illustrate how difficult is to adjust the vibration test conditions to simulate more connector operating hours and thus to calculate a failure rate (or FIT rate) with a good confidence level.

Accordingly, a method for determining a failure rate of an electrical connector, within a reasonable time and costs remains desired.

### SUMMARY

The disclosure is directed towards an innovative solution to the problems presented in the preceding BACKGROUND section. The object of the disclosure is a method for determining the failure rate of a batch of electrical connectors, including the following steps:
Making at least one sample of electrical connector degraded to exhibit a normal contact force less than a force threshold, less than the mean force of the batch;
Determining a probability of the occurrence of at least one sample within the batch, in function of the threshold force;
Applying a vibration test to at least one sample;
Obtaining a failure rate of the sample; and
Calculating a failure rate of the batch by multiplying the failure rate of the sample by the probability.

Some specific features or embodiments, usable alone or in combination, are:
Degrading the sample by mechanical, vibratory and/or thermal aging until reaching the desired normal force.
Selecting the sample is from the batch.
Determining the probability by assuming a normal distribution of the normal force within the batch.
Choosing the threshold force distant from the mean force at least off 30, by lesser value.
Applying the vibration test according to an automotive standard, such as DIN/TS 70214:2024-01.
Determining the failure rate of the sample by calculating the ratio of the number of failing samples at the end of the vibration test to the total number of the sample.
Failing a sample s is failing when its connector resistance is greater than a resistance threshold.
Simulating the prolongation of the duration of the vibration test extrapolating the connector resistance according to a lognormal or Weibull law, until obtaining the failure.
Selecting the sample size to be at least equal to fifty.

### BRIEF DESCRIPTION OF THE DRAWINGS

Others features, details, and advantages of the disclosure will become more apparent from the detailed illustrating description given hereafter with respect to the drawings on which:

FIG. 1 shows diagram of a normal distribution.

FIG. 2 shows a flow diagram of a method for determining a failure rate of a batch of electrical connectors according to some embodiments.

### DETAILED DESCRIPTION

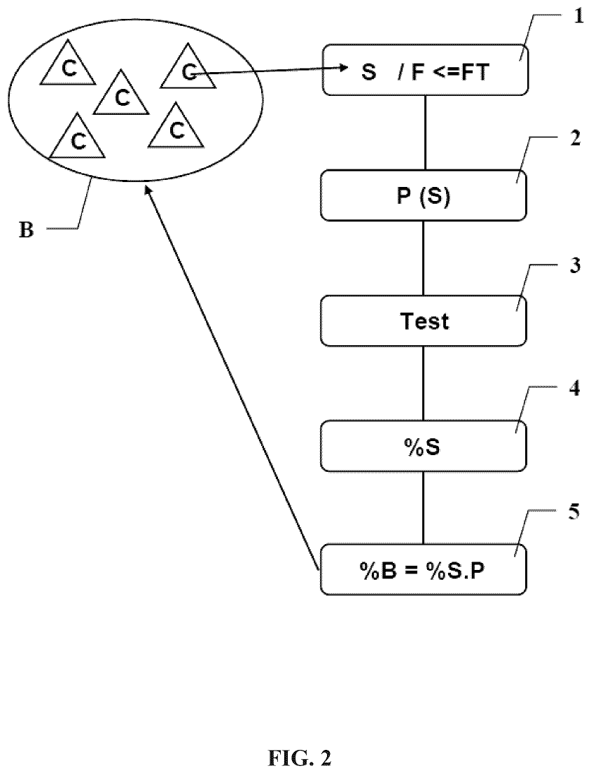

As illustrated in FIG. 2, the disclosure concerns a method for determining a failure rate % B of a batch B of electrical connectors C. An electrical connector C includes at least two terminals. The terminals are tested in contact one with each other. To simulate the operating lifespan of a connector, a connector is submitted to a vibration test according to a vibration profile.

The vibration profile is designed to be representative of the operating environment of the connector during its life. For example, a connector in an automobile is submitted to vibrations of certain waves shapes and intensities. The vibration profile reflects this: the applied vibration profile is indicative of the automobile vibrations. However, the vibration profile is “amplified”, typically in amplitude or in occurrences, to simulate a quicker ageing, to save time.

During its lifespan, which typically is 10 years, a connector C is operational for about 500 hours. By testing 50 connectors samples in parallel, this is equivalent to 250,000 operating hours. This can be simulated by a three-week standard test, having a duration of about 500 h. However, despite this “acceleration” of a factor of 500, 250,000 hours is far from the goal of 10° operating hours, where failures are about to occur.

Accordingly, the aim of the disclosure is to be able to “accelerate” the process furthermore.

The main idea of the disclosure is to consider that the normal force F of the connector C is a most influencing parameter to induce an electrical failure. The lower the normal force F, the shorter the life of the connector C. Moreover, it is assumed that the normal force F can be probabilistically correlated to the failure rate % S.

To ensure maintaining a connection between the at least two terminals, the elasticity of at least one of the terminals is required. This elasticity provides a measurable force appearing between the at least two terminals. The normal component, which is the component measured perpendicularly with respect to the contact, of the force, is called the normal force F.

The main idea of the disclosure is to apply a vibration test to a sample S showing a reduced normal force F. Since the normal force F is reduced, the connector C is expected to fail sooner, leading either to a shortened vibration test duration, and thus a gain of time, or to a vibration test ending nearer to a failure, thus increasing the confidence level of the test's result, by minimizing the amount of extrapolation needed.

Knowing the distribution of connectors C according to their normal force F, it is possible to determine a probability P of occurrence of such a sample S of connector C.

The vibration test provides a failure rate % S of the degraded sample S.

It is then possible to calculate a failure rate % B for the whole batch B by multiplying the failure rate % S of the sample S by the probability P.

So, the method includes the following steps, as illustrated in FIG. 2:

STEP 1: making at least one sample S of electrical connector C degraded to exhibit a reduced contact normal force F, which is less than a force threshold FT, so at least less than the mean force FM of the batch B,

STEP 2: determining a probability P of occurrence of at least one sample S within the batch, in function of the threshold force FT,

STEP 3: applying a vibration test to at least one sample S,

STEP 4: obtaining a failure rate % S of the sample S,

STEP 5: calculating a failure rate % B of the batch B by multiplying the failure rate % S of the sample S by the probability P.

During STEP 1, a sample S is made. Starting from a connector C, its normal force F can be measured. If the normal force F is lesser than a force threshold FT, the connector C can become a sample S. If the normal force F is greater than the force threshold FT, the connector C is operated until its normal force F becomes lesser than the force threshold FT.

The operating, intended to degrade the normal force F, can be mechanical, vibratory and/or thermal. Mechanical means a direct action, such as alternate plying, applied to at least one of the terminals to reduce the connector's rappelling force and thus the normal force F. Vibratory means applying a vibration profile, to age the connector C. This is quite like applying a vibration test, leading to accelerated ageing. Thermal means applying a thermal profile, to age the connector C in a similar way. Whatever the degradation method chosen, the normal force F is measured, and the connector C becomes a valid sample S, when the normal force F is lesser than or equal to the force threshold FT.

For sample S to be representative of batch B, as illustrated in FIG. 2, sample S is made from a connector C selected from batch B, whose failure rate % B is to be determined.

Knowing the normal force F of a sample S, during STEP 2, its probability P can be determined by knowing the distribution of normal force F within batch B. The distribution is a function giving a probability of occurrence P in function of the normal force F. Knowing the manufacturing characteristic of batches B produced, one can determine the type of distribution encountered.

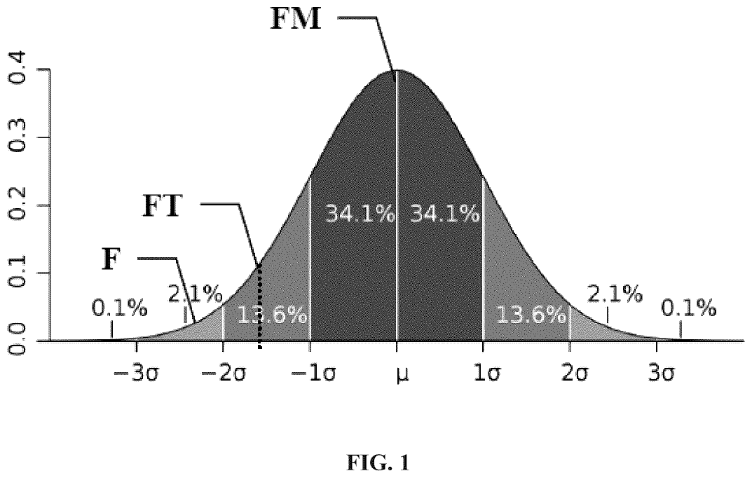

For this purpose, the distribution of the normal force F can be assumed to be a gaussian or a normal distribution within batch B, as illustrated in FIG. 1. The gaussian function is known and is fully characterized by its mean u, here the mean force FM and its standard deviation σ, both known for each batch B. Accordingly, the normal force For alternately the threshold force FT, can be associated to a probability P of occurrence. Reciprocally, for a given probability P, the normal force F can be determined, when asserting a value either lesser or greater than the mean force FM, due to the symmetry of the normal distribution.

The threshold force FT is chosen as small as possible. The smaller the normal force F is, the sooner a failure could be expected. So, the force threshold FT is chosen distant from the mean force FM. The weaker the normal force F or the threshold force FT is, the lower the probability P is, thus leading to a greater multiplying factor. However, if the normal force F becomes too small, confidence level of the test could become at stake, and it could be difficult to obtain such a degradation of the normal force F. A good trade on is a force threshold FT value between 3 σ and 6 σ from the mean force FM, by lesser value.

For example, at 6 σ, negative side, the normal force Fis 33% lesser than the mean force FM. The probability of occurrence is 1/294,100. This leads to a probability of occurrence of 1/147,050. A factor of 2 must be introduced to consider both sides of the distribution curve. This provides a 147050 multiplying factor.

The threshold force FT can be related to the acceptance threshold of the production, to be 1 σ below. For example, if the batch B is of a production whose acceptance threshold is 3 σ: a connector is considered good if its normal force F is included between −3 σ and 3 σ, the force threshold FT of the degraded sample S could preferably be at 4 σ from the mean force FM, by lesser value.

The vibration test used to test at least one sample S can be any vibration test, if its profile is relevant to the intended usual use of the connector C and the test's duration can be related to a real-world duration.

According to another feature, the vibration test is applied according to an automotive standard, e.g., DIN/TS 70214:2024-01.

Among the at least one sample S submitted to the test, some of them would eventually fail during the application of the vibration test. The failure rate % S of at least one sample S is determined, during STEP 4, par dividing the number of failing sample S at the end of the vibration test, by the total number of sample S.

To determine if a sample S had failed, the electrical connector resistance R is used. During the lifespan of a connector C, or during a vibration test, the electrical resistance R of the connector C tends to rise. It rises until it becomes too high, leading to a degradation of the connector or even to fire. The electrical connector resistance R can be measured. Thus, a resistance threshold RT, indicative of failure, is chosen. A sample S is failing when, at the end of the vibration test, its connector resistance R is greater than the resistance threshold RT.

When, among other causes, the normal force F is not enough degraded, the vibration test could not be sufficient to obtain a (significant amount of) failure. In such a case, a prolongation of the duration of the vibration test can be simulated by extrapolating the connector resistance R according to a lognormal or Weibull law, until obtaining the failure. This may be necessary to avoid a failure rate % S equal to zero.

The failure rate % S of the sample S or the failure rate % B of batch B can be made to the scale. For instance, to get failure rates in FIP unit, they must be multiplied by 109.

To provide a multiplying factor without increasing too much the cost of the vibration test, the total number of sample S is at least equal to fifty.

While the invention has been described with reference to an exemplary embodiment(s), it will be understood by those skilled in the art that various changes may be made, and equivalents may be substituted for elements thereof without departing from the scope of the invention. In addition, many modifications may be made to adapt a particular situation or material to the teachings of the invention without departing from the essential scope thereof. Therefore, it is intended that the invention is not limited to the disclosed embodiment(s), but that the invention will include all embodiments falling within the scope of the appended claims.

As used herein, ‘one or more’ includes a function being performed by one element, a function being performed by more than one element, e.g., in a distributed fashion, several functions being performed by one element, several functions being performed by several elements, or any combination of the above.

It will also be understood that, although the terms first, second, etc., are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

Additionally, while terms of ordinance or orientation may be used herein these elements should not be limited by these terms. All terms of ordinance or orientation, unless stated otherwise, are used for purposes distinguishing one element from another, and do not denote any particular order, order of operations, direction or orientation unless stated otherwise.

### LISTING OF REFERENCE NUMBERS USED

B batch
C connector.
F normal force
FM mean force
FT threshold force
P probability
R connector resistance
RT resistance threshold
S sample
%B batch failure rate
%S sample failure rate
1-5 method steps

1. A method for determining a failure rate of a batch of electrical connectors, comprising:
making at least one sample of electrical connector degraded to exhibit a normal contact force less than a force threshold, less than a mean force of the batch;
determining a probability of occurrence of the at least one sample within the batch, in function of the threshold force;
applying a vibration test to the at least one sample;
obtaining a failure rate of the sample; and
calculating a failure rate of the batch by multiplying the failure rate of the sample by the probability.

2. The method according to claim 1, wherein the degradation of the sample is done by mechanical, vibratory and/or thermal ageing until reaching the normal force desired.

3. The method according to claim 1, wherein the sample is from the batch.

4. The method according to claim 1, wherein the probability is determined by assuming a normal distribution of the normal force within the batch.

5. The method according to claim 1, wherein the threshold force is chosen distant from the mean force at least off 30, by lesser value.

6. The method according to claim 1, wherein the vibration test is applied according to an automotive standard.

7. The method according to claim 6, wherein the automotive standard is DIN/TS 70214:2024-01.

8. The method according to claim 1, wherein the failure rate of the sample is determined by a ratio of a number of failing samples at an end of the vibration test to a total number of samples.

9. The method according to claim 8, wherein a sample is determined to fail when its connector resistance is greater than a resistance threshold.

10. The method according to claim 8, wherein a prolongation of a duration of the vibration test is simulated by extrapolating connector resistance according to a lognormal or Weibull law, until obtaining the failure.

11. The method according to claim 1, wherein a total number of samples is at least equal to fifty.
